(19) United States
(12) Patent Application Publication
(10) Pub. No.: US 2023/0174083 A1
(43) Pub. Date: Jun. 8, 2023

(54) DETERMINING A COMPUTATIONAL EFFORT OF A VIRTUAL TEST

(71) Applicant: dSPACE GmbH, Paderborn (DE)

(72) Inventors: Eduard Miller, Paderborn (DE); Renate Loeffler, Paderborn (DE); Patrick Bouillon, Paderborn (DE); Sebastian Bannenberg, Paderborn (DE); Christian Hoelscher, Paderborn (DE)

(21) Appl. No.: 17/680,387

(22) Filed: Feb. 25, 2022

(30) Foreign Application Priority Data
Dec. 6, 2021 (DE) 102021132007.0

(51) Int. Cl. B60W 50/06; G07C 5/08

(52) U.S. Cl. CPC B60W 50/06; G07C 5/0808; G07C 5/0816; B60W 2050/065

(57) ABSTRACT

A computer-implemented method for determining a computational effort of a virtual test of a device for driving a motor vehicle at least partly autonomously includes: providing at least one parameter set of driving situation parameters and of configuration data of a first algorithm that performs the virtual test, wherein the virtual test performed by the first algorithm simulates the at least one parameter set of driving situation parameters, and wherein the result of the simulation is used to determine at least one further parameter set of driving situation parameters that is simulated in a subsequent iteration; applying a second algorithm to the at least one parameter set of driving situation parameters and the configuration data of the first algorithm; and outputting at least one numerical value that represents the computational effort of the virtual test.

### CROSS-REFERENCE TO PRIOR APPLICATIONS

This application claims benefit to German Patent Application No. DE 102021132007.0, filed on Dec. 6, 2021, which is hereby incorporated by reference herein.

### FIELD

The present invention relates to a computer-implemented method for determining a computational effort of a virtual test of a device for driving a motor vehicle at least partly autonomously.

The present invention further relates to a computer-implemented method for providing a machine learning algorithm for determining a computational effort of a virtual test of a device for driving a motor vehicle at least partly autonomously.

In addition, the invention relates to a testing device for determining a computational effort of a virtual test of a device for driving a motor vehicle at least partly autonomously.

### BACKGROUND

Driver assistance systems such as adaptive speed regulators and/or functions for highly automated driving can be verified or validated using various test methods. In particular, simulations can be used.

The effort required, in particular the time spent and/or costs involved, for testing these kinds of vehicle functions using simulations is typically high since a large number of possible driving situations potentially have to be tested. In some cases, therefore, executing a test case using an intelligent test control (ITC) algorithm can take a very long time and require a lot of resources.

However, it is often necessary to be able to estimate how long the test will take and how expensive it will be, for example to be able to budget for the execution of the test or determine how many computing nodes have to be made available.

Using ITC exacerbates the problem since it is not yet possible in the test definition to calculate how many simulations have to be run through. This is calculated dynamically by the ITC algorithm depending on the results of the individual passes. In summary, the estimating is thus dependent on the ITC algorithm, the duration of execution of the various simulations, and the number of nodes used.

Previously, the problem has been able to be circumvented by limiting the execution of the tests to the required minimum, and monitoring employees closely (e.g., only being able to launch a simulation through authorization processes). Alternatively, the costs incurred can be accepted.

### SUMMARY

In an exemplary embodiment, the present invention provides a computer-implemented method for determining a computational effort of a virtual test of a device for driving a motor vehicle at least partly autonomously. The method includes: providing at least one parameter set of driving situation parameters and of configuration data of a first algorithm that performs the virtual test, wherein the virtual test performed by the first algorithm simulates the at least one parameter set of driving situation parameters, and wherein the result of the simulation is used to determine at least one further parameter set of driving situation parameters that is simulated in a subsequent iteration; applying a second algorithm to the at least one parameter set of driving situation parameters and the configuration data of the first algorithm, which performs the virtual test, for determining the computational effort of the virtual test, performed by the first algorithm, of the device for driving the motor vehicle at least partly autonomously; and outputting at least one numerical value that represents the computational effort of the virtual test.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a flowchart of a method for determining, using a testing device, a computational effort of a virtual test of a device for driving a motor vehicle at least partly autonomously according to a preferred embodiment of the invention; and

FIG. 2 is a flowchart of a method for providing a machine learning algorithm for determining a computational effort of a virtual test of a device for driving a motor vehicle at least partly autonomously.

Like reference signs designate like elements in the drawings unless otherwise indicated.

### DETAILED DESCRIPTION

Exemplary embodiments of the invention improve existing test procedures for driver assistance systems so as to make it possible to determine a computational effort of a simulation of a test case.

In an exemplary embodiment, the invention provides a method for determining a computational effort of a virtual test of a device for driving a motor vehicle at least partly autonomously.

In an exemplary embodiment, the invention provides a computer-implemented method for determining a computational effort of a virtual test of a device for driving a motor vehicle at least partly autonomously.

In an exemplary embodiment, the invention provides a computer-implemented method for providing a machine learning algorithm for determining a computational effort of a virtual test of a device for driving a motor vehicle at least partly autonomously.

In an exemplary embodiment, the invention provides a testing device for determining a computational effort of a virtual test of a device for driving a motor vehicle at least partly autonomously.

The invention relates to a computer-implemented method for determining a computational effort of a virtual test of a device for driving a motor vehicle at least partly autonomously.

The method comprises providing at least one parameter set of driving situation parameters and of configuration data of a first algorithm that performs the virtual test, the virtual test performed by the first algorithm simulating the at least one parameter set of driving situation parameters, and the result of the simulation being used to determine at least one further parameter set of driving situation parameters that is simulated in a subsequent iteration.

The method further comprises applying a second algorithm to the at least one parameter set of driving situation parameters and the configuration data of the first algorithm, which performs the virtual test, for determining the computational effort of the virtual test, performed by the first algorithm, of the device for driving the motor vehicle at least partly autonomously, and outputting at least one numerical value that represents the computational effort of the virtual test.

The invention further relates to a computer-implemented method for providing a machine learning algorithm for determining a computational effort of a virtual test of a device for driving a motor vehicle at least partly autonomously.

The method comprises providing a first training dataset of driving situation parameters and of configuration data of a first algorithm that performs the virtual test, and providing a second training dataset of numerical values representing a computational effort of the virtual test.

In addition, the method comprises training the machine learning algorithm using the driving situation parameters, the configuration data of the first algorithm that performs the virtual test, and the numerical values representing the computational effort of the virtual test, via an optimization algorithm that calculates an extremum of a loss function.

A testing device determines a computational effort of a virtual test of a device for driving a motor vehicle at least partly autonomously.

The testing device comprises means for providing at least one parameter set of driving situation parameters and of configuration data of a first algorithm that performs the virtual test, the virtual test performed by the first algorithm simulating the at least one parameter set of driving situation parameters, and the result of the simulation being usable to determine at least one further parameter set of driving situation parameters that is simulated in a subsequent iteration.

The testing device further comprises a controller configured to apply the second algorithm to the at least one parameter set of driving situation parameters and the configuration data of the first algorithm, which performs the virtual test, for determining the computational effort of the virtual test, performed by the first algorithm, of the device for driving the motor vehicle at least partly autonomously, and the controller being configured to output at least one numerical value representing the computational effort of the virtual test.

The invention further relates to a computer program comprising program code for carrying out the method according to the invention when the computer program is executed on a computer.

Exemplary embodiments of the present invention provide a preliminary estimation of a computational effort of a virtual test of a device for driving a motor vehicle at least partly autonomously.

By applying the second algorithm to the at least one parameter set of driving situation parameters and the configuration data of the first algorithm, which performs the virtual test, for determining the computational effort of the virtual test, performed by the first algorithm, of the device for driving the motor vehicle at least partly autonomously, it is advantageously possible to determine the computational effort using information from the scenario, such as for how long a simulation runs if successful.

According to a preferred embodiment of the invention, the at least one parameter set of driving situation parameters comprises at least one surroundings parameter describing the surroundings of the motor vehicle, and at least one ego parameter describing the state of the motor vehicle. The state space thus generated can therefore depict a multiplicity of possible test cases.

According to another preferred embodiment of the invention, the configuration data of the first algorithm that performs the virtual test comprise value ranges, which are to be tested, of the driving situation parameters, a step size of the driving situation parameters to be tested, which in particular is either predetermined or parameterizable by the first algorithm, and/or a number of simulations per iteration. As a result, a potential number of parameter variations of a test case and a computational effort of a particular iteration can be determined, for example.

According to another preferred embodiment of the invention, the second algorithm outputs a first numerical value, which represents a minimum computational effort of the virtual test, and a second numerical value, which represents a maximum computational effort of the virtual test.

The invention thus provides a preliminary estimation. This includes a worst-case and best-case estimation for the simulations to be executed, on the basis of a history.

According to another preferred embodiment of the invention, determining the computational effort of the virtual test by the second algorithm comprises calculating an average computational effort, the second algorithm outputting a third numerical value, which represents the average computational effort.

On the basis of said preliminary estimation, the user can budget for the simulations more effectively. By selecting the computing nodes to be used, it is thus possible to calculate when the test execution will end and the costs that will be incurred as a result.

According to another preferred embodiment of the invention, the results of each simulation, in particular a duration and/or the computational effort of each simulation, are stored in a database, and the average computational effort being determined using the stored simulation results.

Information on previous passes, for example a number of simulations per iteration and/or a number of iterations, is thus stored in an ITC database. This makes the estimations more precise.

According to another preferred embodiment of the invention, the computational effort of the virtual test, as determined by the second algorithm, is updated during the runtime of the first algorithm using the average computational effort, in particular of previous iterations of the virtual test, stored in the database.

During the runtime of the first algorithm, the user thus receives a continuous update to a provisional computational effort of the test case being performed.

According to another preferred embodiment of the invention, a number of simulations per iteration, a number of iterations, an identifier of a type of the first algorithm, an identifier of the driving situation parameters, and/or a value range, which is to be tested, of the driving situation parameters are additionally stored in the database.

As a result, the parameters related to the test algorithm can be calculated more precisely in advance, and these are then used when determining the provisional computational effort of the test case.

According to another preferred embodiment of the invention, the second algorithm performs a first computational-effort determination using the at least one parameter set of driving situation parameters, and a second computational-effort determination using the configuration data of the first algorithm that performs the virtual test, the at least one numerical value that represents the computational effort of the virtual test being calculated using a result of the first computational-effort determination and a result of the second computational-effort determination.

The combination of the computational-effort determination using the driving situation parameters and the configuration data can thus advantageously enable more precise determination of the provisional computational effort.

According to another preferred embodiment of the invention, a numerical value of a number of computing nodes used to perform the virtual test is provided, the numerical value that is output by the second algorithm and represents the computational effort of the virtual test relating to the provided number of computing nodes that are used.

Via the preliminary calculation of the provisional computational effort of the test case, together with the number of nodes and the costs per node, provisionally incurred costs can thus be updated and fed back to the user.

According to another preferred embodiment of the invention, a criterion for aborting the virtual test, performed by the first algorithm, of the device for driving a motor vehicle at least partly autonomously is provided, the criterion being met when a predetermined computational effort is reached.

If a required computational effort exceeds the previously set abort criterion, the user is thus able either to abort the calculation or to continue with the calculation using a new estimation of a provisionally remaining computational effort.

According to another preferred embodiment of the invention, the first algorithm selects initial values of the driving situation parameters and adapts them in subsequent iterations using simulation results.

Over time, the ITC algorithm thus collects statistical information for a scenario and stores it with the scenario. The more passes, the more accurate the estimated worst-case and best-case times.

The features described herein for determining a computational effort of a virtual test of a device for driving a motor vehicle at least partly autonomously apply likewise to a testing device according to the invention for determining a computational effort of a virtual test of a device for driving a motor vehicle at least partly autonomously, and vice versa.

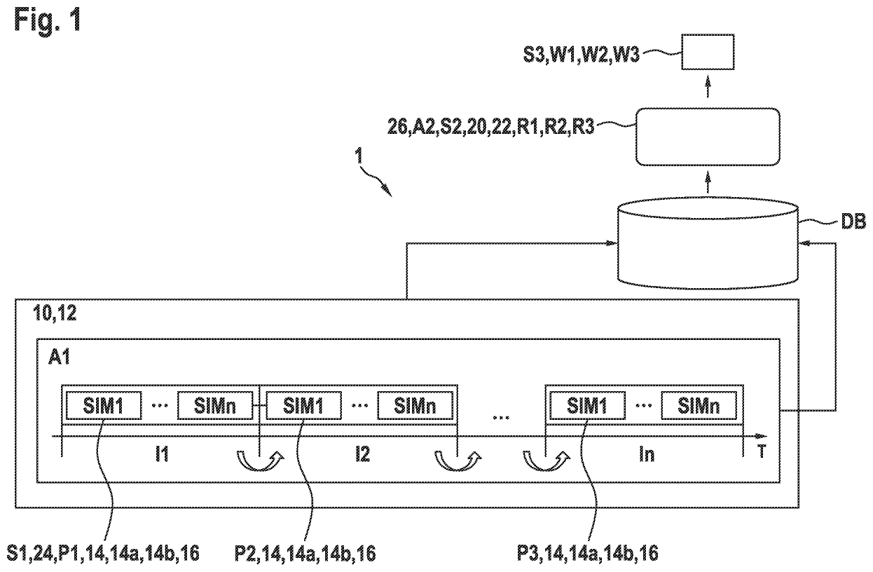

The method shown in FIG. 1 for determining a computational effort of a virtual test 10 of a device 12 for driving a motor vehicle at least partly autonomously comprises providing S1 at least one parameter set P1 of driving situation parameters 14 and of configuration data 16 of a first algorithm A1 that performs the virtual test 10, the virtual test 10 performed by the first algorithm A1 simulating at least one parameter set P1 of driving situation parameters 14, and the result of the simulation being used to determine at least one further parameter set P2, P3 of driving situation parameters 14 that is simulated in a subsequent iteration I2-In.

The at least one parameter set P1 of driving situation parameters 14 comprises at least one surroundings parameter 14a describing the surroundings of the motor vehicle, and at least one ego parameter 14b describing the state of the motor vehicle.

The first algorithm A1 selects initial values of the driving situation parameters 14 and adapts them in subsequent iterations I2-In using simulation results.

The method further comprises applying S2 a second algorithm A2 to the at least one parameter set P1 of driving situation parameters 14 and the configuration data 16 of the first algorithm A1, which performs the virtual test 10, for determining the computational effort of the virtual test 10, performed by the first algorithm A1, of the device 12 for driving the motor vehicle at least partly autonomously, and outputting S3 at least one numerical value W1, W2, W3 that represents the computational effort of the virtual test 10.

The configuration data 16 of the first algorithm A1 that performs the virtual test 10 comprise value ranges, which are to be tested, of the driving situation parameters 14, a step size of the driving situation parameters 14 to be tested, which in particular is either predetermined or parameterizable by the first algorithm A1, and/or a number of simulations SIM1-SIMn per iteration I1-In.

The second algorithm A2 outputs a first numerical value W1, which represents a minimum computational effort R1 of the virtual test 10, and a second numerical value W2, which represents a maximum computational effort R2 of the virtual test 10.

Determining the computational effort R1, R2 of the virtual test 10 by the second algorithm A2 comprises calculating an average computational effort R3, the second algorithm A2 outputting a third numerical value W3, which represents the average computational effort R3.

The results of each simulation in particular a duration T and/or the computational effort R1, R2, R3 of each simulation SIM1-SIMn, are stored in a database DB. In the process, the average computational effort R3 is determined using the stored simulation results.

The computational effort R1, R2, R3 of the virtual test 10, as determined by the second algorithm A2, is updated during the runtime of the first algorithm A1 using the average computational effort R3, in particular of previous iterations I1-In of the virtual test 10, stored in the database DB.

A number of simulations SIM1-SIMn per iteration I1-In, a number of iterations I1-In, an identifier of a type of the first algorithm A1, an identifier of the driving situation parameters 14, and/or a value range, which is to be tested, of the driving situation parameters 14 are additionally stored in the database DB.

The second algorithm A2 performs a first computational-effort determination 20 using the at least one parameter set P1 of driving situation parameters 14, and a second computational-effort determination 22 using the configuration data 16 of the first algorithm A1 that performs the virtual test 10.

In the process, the at least one numerical value W1, W2, W3 representing the computational effort R1, R2, R3 of the virtual test 10 is calculated using a result of the first computational-effort determination 20 and a result of the second computational-effort determination 22.

In addition, the numerical value W1, W2, W3 of a number of computing nodes used to perform the virtual test 10 is provided. The numerical value W1, W2, W3 output by the second algorithm A2 and representing the computational effort R1, R2, R3 of the virtual test 10 relates to the provided number of computing nodes that are used.

In addition, a criterion for aborting the virtual test 10, performed by the first algorithm A1, of the device 12 for driving a motor vehicle at least partly autonomously is provided. The criterion is met when a predetermined computational effort R1, R2, R3 is reached.

The testing device 1 comprises means 24 for providing at least one parameter set P1 of driving situation parameters 14 and of configuration data 16 of a first algorithm A1 that performs the virtual test 10, the virtual test 10 performed by the first algorithm A1 simulating the at least one parameter set P1 of driving situation parameters 14, and the result of the simulation SIM1-SIMn being usable to determine at least one further parameter set P2, P3 of driving situation parameters 14 that is simulated in a subsequent iteration I2-In. Means 24 may include, for example, a component, a device, or a system which generates the at least one parameter set P1 and provides it to the controller, and/or a user input interface through which a user input provides the at least one parameter set P1, wherein the user input interface is arranged in the testing device or on another component, device, or system.

The testing device 1 further comprises a controller 26 configured to apply the second algorithm A2 to the at least one parameter set P1 of driving situation parameters 14 and the configuration data 16 of the first algorithm A1, which performs the virtual test 10, for determining the computational effort R1, R2, R3 of the virtual test 10, performed by the first algorithm A1, of the device 12 for driving the motor vehicle at least partly autonomously, and the controller 26 being configured to output at least one numerical value W1, W2, W3 representing the computational effort R1, R2, R3 of the virtual test 10.

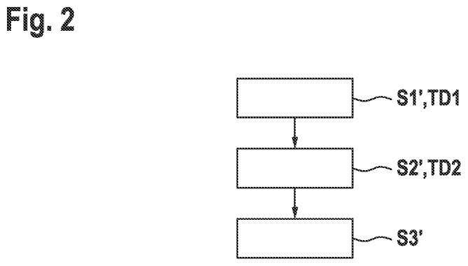

FIG. 2 is a flowchart of a method for providing a machine learning algorithm for determining a computational effort of a virtual test of a device for driving a motor vehicle at least partly autonomously.

The method comprises providing S1′ a first training dataset TD1 of driving situation parameters 14 and of configuration data 16 of a first algorithm A1 that performs the virtual test 10.

The method further comprises providing S2′ a second training dataset TD2 of numerical values W1, W2, W3 representing a computational effort R1, R2, R3 of the virtual test 10.

In addition, the method comprises training S3′ the machine learning algorithm A2 using the driving situation parameters 14, the configuration data 16 of the first algorithm A1 that performs the virtual test 10, and the numerical values W1, W2, W3 representing the computational effort R1, R2, R3 of the virtual test 10, via an optimization algorithm that calculates an extremum of a loss function.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 testing device
10 virtual test
12 device
14 driving situation parameters
14a surroundings parameter
14b ego parameter
16 configuration data
20 first computational-effort determination
22 second computational-effort determination
24 component
26 controller
A1 first algorithm
A2 second algorithm
DB database
I1-In iteration
P1 parameter set
P2, P3 additional parameter sets
R1, R2, R3 computational effort
S1-S3 method steps
S1′-S3′ method steps
SIM1-SIMn simulations
T time
TD1 first training dataset
TD2 second training dataset
W1, W2, W3 numerical value

1. A computer-implemented method for determining a computational effort of a virtual test of a device for driving a motor vehicle at least partly autonomously, comprising:
providing at least one parameter set of driving situation parameters and of configuration data of a first algorithm that performs the virtual test, wherein the virtual test performed by the first algorithm simulates the at least one parameter set of driving situation parameters, and wherein the result of the simulation is used to determine at least one further parameter set of driving situation parameters that is simulated in a subsequent iteration;
applying a second algorithm to the at least one parameter set of driving situation parameters and the configuration data of the first algorithm, which performs the virtual test, for determining the computational effort of the virtual test, performed by the first algorithm, of the device for driving the motor vehicle at least partly autonomously; and
outputting at least one numerical value that represents the computational effort of the virtual test.

2. The computer-implemented method according to claim 1, wherein the at least one parameter set of driving situation parameters comprises at least one surroundings parameter describing the surroundings of the motor vehicle, and at least one ego parameter describing the state of the motor vehicle.

3. The computer-implemented method according to claim 1, wherein the configuration data of the first algorithm that performs the virtual test comprise value ranges, which are to be tested, of the driving situation parameters, a step size of the driving situation parameters to be tested, which is either predetermined or parameterizable by the first algorithm, and/or a number of simulations per iteration.

4. The computer-implemented method according to claim 1, wherein the second algorithm outputs a first numerical value which represents a minimum computational effort of the virtual test and a second numerical value which represents a maximum computational effort of the virtual test.

5. The computer-implemented method according to claim 4, wherein determining the computational effort of the virtual test by the second algorithm comprises calculating an average computational effort, wherein the second algorithm outputs a third numerical value which represents the average computational effort.

6. The computer-implemented method according to claim 5, wherein the results of each simulation, in particular a duration and/or the computational effort of each simulation, are stored in a database, and wherein the average computational effort is determined using the stored simulation results.

7. The computer-implemented method according to claim 6, wherein a number of simulations per iteration, a number of iterations, an identifier of a type of the first algorithm, an identifier of the driving situation parameters, and/or a value range, which is to be tested, of the driving situation parameters are additionally stored in the database.

8. The computer-implemented method according to claim 5, wherein the computational effort of the virtual test, as determined by the second algorithm, is updated during the runtime of the first algorithm using the average computational effort, in particular of previous iterations of the virtual test, stored in the database.

9. The computer-implemented method according to claim 1, wherein the second algorithm performs a first computational-effort determination using the at least one parameter set of driving situation parameters, and a second computational-effort determination using the configuration data of the first algorithm that performs the virtual test, wherein the at least one numerical value representing the computational effort of the virtual test is calculated using a result of the first computational-effort determination and a result of the second computational-effort determination.

10. The computer-implemented method according to claim 1, wherein a numerical value of a number of computing nodes used to perform the virtual test is provided, wherein the numerical value output by the second algorithm and representing the computational effort of the virtual test relates to the provided number of computing nodes that are used.

11. The computer-implemented method according to claim 1, wherein a criterion for aborting the virtual test, performed by the first algorithm, of the device for driving a motor vehicle at least partly autonomously is provided, wherein the criterion is met when a predetermined computational effort is reached.

12. The computer-implemented method according to claim 1, wherein the first algorithm selects initial values of the driving situation parameters and adapts them in subsequent iterations using simulation results.

13. A computer-implemented method for providing a machine learning algorithm for determining a computational effort of a virtual test of a device for driving a motor vehicle at least partly autonomously, comprising:
providing a first training dataset of driving situation parameters and of configuration data of a first algorithm that performs the virtual test;
providing a second training dataset of numerical values representing a computational effort of the virtual test; and
training the machine learning algorithm using the driving situation parameters, the configuration data of the first algorithm that performs the virtual test, and the numerical values representing the computational effort of the virtual test, via an optimization algorithm that calculates an extremum of a loss function.

14. A testing device for determining a computational effort of a virtual test of a device for driving a motor vehicle at least partly autonomously, wherein the testing device comprises one or more processors and one or more non-transitory memories having processor-executable instructions stored thereon, wherein the one or more processors are configured to execute the processor-executable instructions to facilitate the following being performed by the testing device:
obtaining at least one parameter set of driving situation parameters and of configuration data of a first algorithm that performs the virtual test, wherein the virtual test performed by the first algorithm simulates the at least one parameter set of driving situation parameters, and wherein the result of the simulation can be used to determine at least one further parameter set of driving situation parameters that is simulated in a subsequent iteration;
applying the second algorithm to the at least one parameter set of driving situation parameters and the configuration data of the first algorithm, which performs the virtual test, for determining the computational effort of the virtual test, performed by the first algorithm, of the device for driving the motor vehicle at least partly autonomously; and
outputting at least one numerical value representing the computational effort of the virtual test.

15. A non-transitory computer-readable medium having processor-executable instructions stored thereon, wherein the processor-executable instructions, when executed, facilitate performance of the method according to claim 1.
